(19) United States
(12) Patent Application Publication
(10) Pub. No.: US 2020/0194580 A1
(43) Pub. Date: Jun. 18, 2020

(54) NITRIDE SEMICONDUCTOR SUBSTRATE AND NITRIDE SEMICONDUCTOR DEVICE

(71) Applicant: CoorsTek KK, Tokyo (JP)

(72) Inventors: Yoshihisa ABE, Hadano-shi (JP); Kenichi ERIGUCHI, Hadano-shi (JP); Jun KOMIYAMA, Hadano-shi (JP)

(73) Assignee: CoorsTek KK, Tokyo (JP)

(21) Appl. No.: 16/697,332

(22) Filed: Nov. 27, 2019

(30) Foreign Application Priority Data
Dec. 12, 2018 (JP) 2018-232147
Dec. 12, 2018 (JP) 2018-232149
Oct. 4, 2019 (JP) 2019-183837
Oct. 4, 2019 (JP) 2019-183838
Nov. 25, 2019 (JP) 2019-211925

(51) Int. Cl. H01L 29/778; H01L 29/20

(52) U.S. Cl. CPC H01L 29/7787; H01L 29/2003

(57) ABSTRACT

Provided is a nitride semiconductor structure capable of preventing deterioration of transistor characteristics caused by diffusion of a P-type conductive element by using an extremely simple configuration, instead of introducing a diffusion suppression layer. A nitride semiconductor substrate comprises at least a layered structure made of group 13 nitride semiconductors, wherein a first layer, a second layer having a wider band gap than the first layer, and a third layer containing a P-type conductive impurity at a concentration of 5E+18 atoms/cc or more are stacked in this order in the layered structure, and a maximum concentration of P-type conductive impurity in the first layer is 10% or less of the concentration of P-type conductive impurity in the third layer.

### BACKGROUND OF THE INVENTION

### Field of Invention

The present invention relates to a nitride semiconductor substrate suitable for normally-off semiconductor devices, and a nitride semiconductor device using the same.

### Description of the Related Art

With regard to a high electron mobility transistor (HEMT) and the like composed of nitride semiconductors, there is a known technology for forming a support layer for normally-off operation (hereafter referred to as a normally-off support layer), made of a P-type semiconductor and provided on an electron supply layer or immediately under a gate electrode, so as to produce so-called a layered structure for normally-off operation.

For example, JP 5400266 B discloses a normally-off field-effect transistor comprising a liner layer, a channel layer, an electron supply layer and a P-type layer. The liner layer, the channel layer, the electron supply layer and the P-type layer are formed of group-III nitride semiconductors and provided in this order on a (0001) principal surface of a sapphire substrate, a SiC substrate or a GaN substrate, or on a (111) principal surface of a Si substrate. A gate electrode is provided on the P-type layer. The liner layer is formed of an AlN layer and an AlₓGa₁₋ₓN layer (0<x<1) provided thereon, from the substrate side. A forbidden bandwidth of the channel layer is narrower than those of the AlₓGa₁₋ₓN layer and of the electron supply layer.

However, in a case of sequentially depositing the layers by a metal organic chemical vapor deposition (MOCVD) method, which is a common method of producing a HEMT, a P-type conductive impurity doped in the process of forming the normally-off support layer diffuses into the electron supply layer and the channel layer (the electron transit layer), and accordingly causes a trouble in the transistor operation.

It is known that a P-type conductive impurity Mg diffuses faster in a nitride semiconductor layer. Particularly, when a large amount of Mg diffuses into the electron transit layer, electron transport in the two-dimensional electron gas (2DEG) is inhibited and the resistance accordingly is increased, resulting in a device with inferior energy efficiency.

There is a disclosure to solve this at WO 2014/188715. A configuration disclosed therein is composed of: a first semiconductor layer made of InₚAl_{q}Ga_{1-p-q}N (0≤p+q≤1, 0≤p, and 0≤q); a second semiconductor layer formed on the first semiconductor layer and made of InᵣAlₛGa₁₋ᵣ₋ₛN (0≤r+s≤1, 0≤r) having a wider band gap than the first semiconductor layer; a third semiconductor layer selectively formed on the second semiconductor layer and made of InₜAlᵤGa₁₋ₜ₋ᵤN (0≤t+u≤1, 0≤t, and s>u); a fourth semiconductor layer formed on the third semiconductor layer and made of InₓAl_{y}Ga_{1-x-y}N (0≤x+y=1, 0≤x, and 0≤y) having P-type conductivity; and a gate electrode formed on the fourth semiconductor layer. In the configuration, because the third semiconductor layer exists as a diffusion suppression layer between the second semiconductor layer to be a barrier layer of the semiconductor device and the fourth semiconductor layer having P-type conductivity, it becomes possible, even when diffusion of the P-type dopant occur during growth of the fourth semiconductor layer, to reduce the amount of the P-type dopant diffused into the second semiconductor layer, thereby prevent change of the second semiconductor layer into P-type, and accordingly suppress deterioration in contact resistance and sheet resistance. In the semiconductor device of WO 2014/188715, for example, layer thicknesses of the buffer layer, the channel layer, and the barrier layer are 100 nm, 2 μm and 30 nm, and those of the diffusion suppression layer and the P-type conductive layer are 25 nm and 200 nm, respectively.

### SUMMARY OF THE INVENTION

The above-described diffusion suppression layer exerts an effect of preventing the diffusion of a P-type conductive element toward the electron supply layer, but at the same time causes increase of distortion and dislocation due to difference in lattice constants, and accordingly causes trouble in transistor operation. In a case of a transistor specification not permitting use of such a diffusion suppression layer, the method is not effective.

In view of the above-described issue, an object of the present invention is to provide a nitride semiconductor structure capable of preventing the deterioration of transistor characteristics due to the diffusion of a P-type conductive element, by using an extremely simple configuration, even without using a diffusion suppression layer.

A nitride semiconductor substrate of the present invention comprises at least a layered structure made of group 13 nitride semiconductors, wherein, in the layered structure, a first layer, a second layer having a wider band gap than the first layer, and a third layer containing a P-type conductive impurity at a concentration of 5E+18 atoms/cm³ or more are stacked in this order, and a maximum concentration of the P-type conductive impurity in the first layer is 10% or less of the concentration of the P-type conductive impurity in the third layer.

By employing this configuration, it becomes possible to effectively prevent adverse effects of the P-type conductive element on the electron transit layer, without introducing any additional layer such as a diffusion suppression layer.

In the present invention, it is preferable that the first layer, the second layer and the third layer should be made of GaN, AlGaN and GaN, respectively, and that the P-type conductive impurity should be Mg.

Further, provided is a nitride semiconductor substrate including the layered structure according to the present invention preferably formed on a base substrate with a buffer layer made of nitride semiconductors interposed therebetween; and more preferably, the nitride semiconductor substrate has, on the surface of the third layer, conical-shaped pits having an opening with a 10 nm or less inner diameter. It should be noted that the density of the pits is 1E+10/cm² or less.

In addition, provided is a nitride semiconductor device prepared using the nitride semiconductor substrate.

According to the present invention, it is possible to provide a nitride semiconductor substrate that effectively prevents the diffusion of a P-type conductive element into the electron transit layer without introducing an extra layer such as a diffusion suppression layer. A nitride semiconductor device prepared using the nitride semiconductor substrate can be utilized as a high performance semiconductor device.

In view of the above-described issue, an object of the present invention is to provide a nitride semiconductor structure capable of reducing various adverse effects caused by introducing a diffusion suppression layer, while preventing the diffusion of a P-type conductive element toward the electron supply layer.

A nitride semiconductor substrate of the present invention comprises at least a layered structure made of group 13 nitride semiconductors, wherein, in the layered structure, a first layer, a second layer having a wider band gap than the first layer, a third layer with a thickness of 0.25 to 2 nm and having a wider band gap than the second layer, and a fourth layer containing a P-type conductive impurity at a concentration of 5E+18 atoms/cc or more are stacked in this order, and the concentration of the P-type conductive impurity at an interface between the second layer and the third layer is one hundredth or less of that at an interface between the fourth layer and the third layer.

By employing this configuration, it becomes possible to effectively reduce diffusion of the P-type conductive element into the electron supply layer while minimizing adverse effects due to the additionally introduced layer.

In the present invention, it is more preferable that a fifth layer made of a nitride semiconductor should be further provided between the first layer and the second layer, the fifth layer having a thickness of 0.25 to 5 nm and having a wider band gap than the second layer.

In a preferable embodiment of the present invention, the first layer is made of GaN, the second layer is made of AlGaN, the third layer and the fifth layer are made of AlN, the fourth layer is made of GaN, and the P-type conductive impurity is Mg. The preferable embodiment may also be a nitride semiconductor substrate wherein the layered structure is formed on a base substrate with a buffer layer made of nitride semiconductors therebetween.

In another preferable embodiment of the present invention, the fourth layer may have, on its surface, conical-shaped pits having an opening with a 10 nm or less inner diameter. A preferable density of the pits is 1E+10/cm² or less.

A nitride semiconductor device of the present invention is prepared using the nitride semiconductor substrate.

According to the present invention, it is possible to provide a nitride semiconductor substrate capable of effectively reducing diffusion of a P-type conductive element into the electron supply layer, while minimizing adverse effects due to the additionally introduced layer. Accordingly, with regard to a GaN-based HEMT intrinsically operating as a normally-on device, the present invention can provide a nitride semiconductor substrate which simultaneously enables prevention of mobility degradation and normally-off operation. A nitride semiconductor device prepared using the nitride semiconductor substrate of the present invention can be utilized as a high performance semiconductor device.

### BRIEF DESCRIPTION OF DRAWINGS

FIG. 1 is a cross-sectional schematic diagram showing an embodiment of the present invention;

FIG. 2 shows Mg concentration profiles in the depth direction of substrates in Example 1 and Comparative Example 1;

FIG. 3 is a cross-sectional schematic diagram showing another embodiment of the present invention;

FIG. 4 is a schematic graph showing a concentration profile of a P-type conductive impurity according to the present invention; and

FIG. 5 is a cross-sectional schematic diagram showing still another embodiment of the present invention.

### DESCRIPTION OF THE PREFERRED EMBODIMENTS

Hereinafter, the present invention will be described in detail with reference to the drawings.

A nitride semiconductor substrate of the present invention comprises at least a layered structure made of group 13 nitride semiconductors, wherein, in the layered structure, a first layer, a second layer having a wider band gap than the first layer, and a third layer containing a P-type conductive impurity at a concentration of 5E+18 atoms/cm³ or more are stacked in this order, and a maximum concentration of the P-type conductive impurity in the first layer is 10% or less of the concentration of the P-type conductive impurity in the third layer.

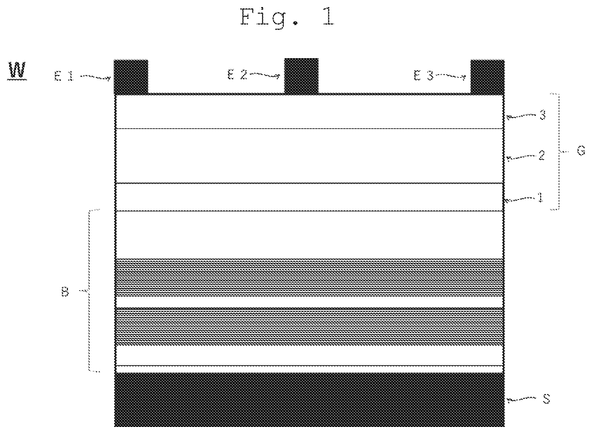

FIG. 1 is a cross-sectional schematic diagram showing an embodiment of the nitride semiconductor substrate according to the present invention. The nitride semiconductor substrate has a HEMT structure in which a layered structure is formed on a substrate of a different material with a buffer layer interposed therebetween. In other words, in a nitride semiconductor substrate W, a buffer layer B is formed on one principal surface of a base substrate S, and a layered structure G is formed thereon. In FIG. 1, also illustrated are electrodes (E1, E2 and E3 represent a drain electrode, a gate electrode and a source electrode, respectively), which are provided to constitute a semiconductor device.

In the schematic diagrams presented in the present invention, shapes are schematically simplified and emphasized for explanation, and the shapes, dimensions and ratios of the details are different from the actual ones. A reference sign is omitted for a configuration which is the same as that already shown, and further, any other configurations unnecessary to explain the present invention are not illustrated.

The base substrate S may be not only silicon (Si) but also silicon carbide (SiC), sapphire (Al₂O₃), aluminum nitride (AlN), gallium nitride (GaN) or the like. It may be made of either a single material or different materials. Its diameter, plane orientation, dopant concentration and off angle may be set optionally.

The buffer layer B has a structure in which plural nitride semiconductor layers are stacked, where any known structure is adopted in accordance with the uses and purposes. A more preferable form of the buffer layer is the one which is prepared by forming an appropriate initial layer first, and then stacking nitride semiconductor layers each composed of one layer or more than one layers which are different from each other in composition and impurity concentration.

Here, the nitride semiconductors each are composed of a combination of group 13 elements, such as gallium (Ga), aluminum (Al) and indium (In), with nitrogen (N) and, if necessary, may be doped with various elements, such as carbon (C), oxygen (O), Si, iron (Fe) and boron (B).

The layered structure G comprises a first layer 1, a second layer 2 having a wider band gap than the first layer 1, and a third layer 3 containing 5E+18 atoms/cm³ or more of a P-type impurity, which are stacked in this order.

The layered structure G in the present invention is a term collectively referring to the first layer 1, the second layer 2 and the third layer 3 which work as a device, and also to various other layers to be added as needed. In the HEMT structure shown in FIG. 1, the first layer 1 corresponds to an electron transit layer, the second layer 2 an electron supply layer, and the third layer a normally-off support layer.

The nitride semiconductor substrate W is not restricted to that having a HEMT structure, but may have any structure in which the buffer layer B and the layered structure G are formed on the base substrate S, and accordingly is preferably used also for other types of power devices capable of operating at higher frequency with higher breakdown voltage.

Known configurations (in terms of layer thickness and impurity concentration) are widely applicable to the first layer 1 and the second layer 2 having a wider band gap than the first layer 1. A material constituting the first layer 1 may be any nitride semiconductor composed of a combination of group 13 elements, such as gallium (Ga), aluminum (Al) and indium (In), described above, with nitrogen (N), and specifically is, for example, GaN, AlGaN or the like. Among these, GaN is preferable. In the present invention, it is preferable that the first layer 1 should be made of a non-doped nitride semiconductor because of its not inhibiting the electron transit.

A material constituting the second layer 2 is not particularly restricted as far as it has a wider band gap than the first layer 1. For example, it may be even a ternary or quaternary mixed crystal. Specific examples are InAlN, AlGaN, InAlGaN and the like, and AlGaN is preferable among them. Here, AlGaN has a composition of AlₓGa₁₋ₓN (0<x≤0.5). The materials just described may be doped with various elements, such as C, Si, Ge, Be, Mg, Zn and Fe, which are used to control the conductivity.

The third layer 3 containing 5E+18 atoms/cm³ or more of a P-type conductive impurity (the normally-off support layer) is formed on the second layer 2. By introducing such a third layer 3, the threshold voltage can be controlled and, for example, a function to cut off electric current without depending on the thickness of the second layer 2, and the like, can be expected. The normally-off support layer, which enables normally-off operation, needs to contain a P-type conductive impurity at a high concentration, specifically at least 5E+18 atoms/cm³ or more, as well known in the prior art.

For the P-type conductive impurity, any of a wide variety of known materials whose doping in the nitride semiconductor induces P-type conductivity may be used. Such materials include not only magnesium (Mg) but also Be and Zn and the like. For example, the P-type conductive impurity is preferred to be Mg when the nitride semiconductor is GaN.

The P-type conductive impurity is doped such that its concentration in the third layer be 5E+18 atoms/cm³ or more, by using known technology. Specifically, a Mg source, such as bis(dicyclopentadienyl)magnesium (Cp₂Mg), is supplied simultaneously with source materials for the third layer (such as trimethylgallium (TMGa)) by vapor growth method, under appropriate control of the supply amounts, growth temperature and growth pressure.

In a specific embodiment of the present invention, the first layer 1 is made of GaN, the second layer 2 of AlGaN, the third layer 3 of GaN, and the P-type conductive impurity is Mg. Preferably, each of the first layer 1 and the third layer 3 has a thickness of 40 nm or more, and the second layer 2, depending on its Al content, has a thickness of 1.5 to 80 nm.

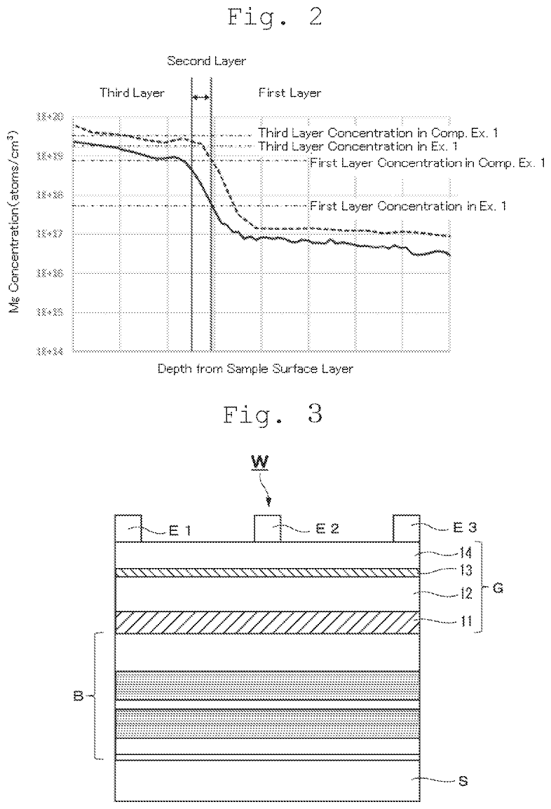

A maximum concentration of the P-type conductive impurity in the first layer 1 is 10% or less of the concentration of the P-type conductive impurity in the third layer 3. FIG. 2 shows, for each of Example 1 and Comparative Example 1 being described later, a concentration profile of the P-type conductive impurity (Mg, as herein used) in the depth direction of the substrate. The horizontal axis represents the depth from the surface of the third layer 3 (Mg-doped GaN) toward the first layer 1 (non-doped GaN). In FIG. 2, the solid line shows a result for Example 1 and the dotted line shows a result for Comparative Example 1.

The maximum concentration of the P-type conductive impurity in the first layer 1 refers to a highest concentration value within the first layer 1 in the depth direction as shown in FIG. 2. Since the concentration gradually decreases with increasing distance from the third layer 3 having a higher Mg concentration, the above-described maximum value usually corresponds to a Mg concentration at an interface between the first layer 1 and the second layer 2.

A method used for measuring the concentration of P-type conductive impurity usually is secondary ion mass spectrometry (SIMS), but there is no particular limitation on the method here. When there occurs local variation in measured concentration values, considering that the local variation may be due to limitation in measurement accuracy, an obviously peculiar value is not taken as the maximum value.

The concentration of the P-type conductive impurity in the third layer 3 refers to an average concentration of the P-type conductive impurity over the whole thickness of the third layer 3. For example, the average value is obtained by choosing five points at equal intervals along the thickness direction and then calculating an average value of concentrations of the P-type conductive impurity at the respective points. It is desirable that the number of chosen points should be at least three for accuracy, and at most nine considering a balance between the measurement cost and the effect of the present invention.

The reason why the concentration of the P-type conductive impurity in the third layer 3 is defined as above will be described below. As shown in FIG. 2, the concentration of the P-type conductive impurity at an interface between the first layer 1 and the second layer 2 is determined by diffusion of the P-type conductive impurity from the third layer 3. At a time when the second layer 2 has been just formed, no amount of the P-type conductive impurity is included either in the second layer 2 or in the first layer 1. During the process of forming the third layer 3 on the second layer 2 by an MOCVD method, the P-type conductive impurity diffuses into the second layer 2 to form a certain concentration profile.

It is assumed that when the P-type conductive impurity concentration at an interface between the third layer 3 and the second layer 2 is low, the P-type conductive impurity concentration at an interface between the second layer 2 and the first layer 1 is also lowered. It accordingly may be said that the P-type conductive impurity concentration at an interface between the second layer 2 and the first layer 1 is determined at an early stage in forming the layer 3.

The fact is, however, the concentration profile of the P-type conductive impurity diffusing in the second layer 2 and the profile of the P-type conductive impurity formed in the third layer 3 vary depending on the conditions, such as the growth temperature, growth pressure, and the supply amount and time of source gases, in the process of depositing the third layer 3 until its thickness reaches a predetermined value.

While the point of the present invention lies in comparison between the P-type conductive impurity concentrations in the first layer 1 and in the third layer 3, it is difficult to perform the comparison using the entirety of each of various concentration profiles, of the P-type conductive impurity, formed in the third layer 3. Therefore, the P-type conductive impurity concentration profile in the third layer 3 is substituted by the average value thereof. The use of such a means causes no significant degradation of the accuracy, enables simple and low-cost operation, and raises no practical problem.

It has turned out that when the maximum concentration of P-type conductive impurity in the first layer 1 is 10% or less of the concentration of P-type conductive impurity in the third layer 3, influence of the P-type conductive impurity on a 2DEG formed in the vicinity of an interface between the first layer 1 and the second layer 2 falls within a practically acceptable level. More preferably, the maximum concentration of P-type conductive impurity in the first layer 1 is 5% or less of the concentration of P-type conductive impurity in the third layer 3.

Practically, the shape of P-type conductive impurity concentration profile in the second layer 2 also is considered to affect the 2DEG behavior to some extent. Therefore, by adding an indicator concerning the above-described profile shape to the relationship between the P-type conductive impurity concentrations in the first layer 1 and in the third layer 3, one of more preferred embodiments of the present invention can be expressed.

For example, while the concentration profile of P-type conductive impurity in the second layer 2 basically shows gradual decrease toward the base substrate S in the thickness direction of the second layer 2, it shows an abrupt decrease within the first half part of the thickness (the third layer side) of the second layer 2. The result demonstrates that, as the distance between the 2DEG and the region of high P-type conductive impurity concentration becomes larger, the effect of suppressing deterioration of the mobility, given by the present invention, becomes more remarkable.

For another example, the concentration of P-type conductive impurity in the second layer 2 may have a profile where the concentration is decreased to 10% or less of that of P-type conductive impurity in the third layer 3 at a middle part in the thickness direction of the second layer 2, and be almost kept constant, at the value, between the middle part and the vicinity of an interface between the first layer 1 and the second layer 2.

When the P-type conductive impurity concentration profile in the third layer 3 is produced to be such that the concentration is high from the surface to the vicinity of an interface between the third layer 3 and the second layer 2, and is abruptly decreased only in the vicinity of the interface, the maximum concentration of P-type conductive impurity in the second layer 2 can be reduced. Accordingly, it is possible to suppress, to a preferably lower level, the concentration of P-type conductive impurity at a stage when the P-type conductive impurity diffusing toward the side of the first layer 1 during the formation of the third layer 3 reaches the vicinity of an interface between the first layer 1 and the second layer 2.

As described above, the present invention can effectively prevent the diffusion of P-type conductive impurity into the electron transit layer even without introducing any diffusion suppression layer, and thereby provide a nitride semiconductor substrate that sufficiently secures transistor operation and performance. A nitride semiconductor device prepared using the nitride semiconductor substrate of the present invention can be utilized as a high performance semiconductor device.

A nitride semiconductor substrate of the present invention comprises at least a layered structure made of group 13 nitride semiconductors, wherein, in the layered structure, a first layer, a second layer having a wider band gap than the first layer, a third layer with a thickness of 0.25 to 2 nm and having a wider band gap than the second layer, and a fourth layer containing a P-type conductive impurity at a concentration of 5E+18 atoms/cc or more are stacked in this order, and the concentration of the P-type conductive impurity at an interface between the second layer and the third layer is one hundredth or less of the concentration of the P-type conductive impurity at an interface between the fourth layer and the third layer.

FIG. 3 is a cross-sectional schematic diagram showing an embodiment of the nitride semiconductor substrate of the present invention. The following description will be given assuming that the nitride semiconductor substrate includes a HEMT structure on a substrate of a different material with a buffer layer interposed therebetween. In the nitride semiconductor substrate W, a buffer layer B is formed on one principal surface of a base substrate S, and a layered structure G is formed thereon. The layered structure G comprises a first layer 11, a second layer 12, a third layer 13 and a fourth layer 14. In FIG. 3, also illustrated are electrodes (E1, E2 and E3 represent a drain electrode, a gate electrode and a source electrode, respectively), which are provided to constitute a semiconductor device.

The base substrate S may be not only Si but also silicon carbide (SiC), sapphire (Al₂O₃), aluminum nitride (AlN), GaN or the like. It may also be a ceramic substrate such as a sintered AlN or a metal substrate, as well as a single crystal substrate such as a Si substrate and a SiC substrate. It may be made of either a single material or different materials. Its plane orientation, dopant concentration and off angle may be set optionally.

The buffer layer B has a structure in which plural nitride semiconductor layers are stacked, where any known structure is adopted in accordance with the uses and purposes. A more preferable form of the buffer layer is the one which is prepared by forming an appropriate initial layer first, and then stacking nitride semiconductor layers each composed of one layer or more than one layers which are different from each other in composition and impurity concentration. A nucleation layer, a stress control layer or the like may be optionally inserted between the base substrate S and the buffer layer B.

The nitride semiconductors are each composed of a combination of group 13 elements, such as Ga, aluminum (Al) and indium (In), with nitrogen (N) and, if necessary, may be doped with various elements, such as carbon, oxygen, silicon and iron.

In the layered structure G, the first layer 11, the second layer 12 having a wider band gap than the first layer 11, the third layer 13 with a thickness of 0.25 to 2 nm and having a wider band gap than the second layer 12, and the fourth layer 14 containing 5E+18 atoms/cc or more of a P-type conductive impurity are stacked in this order.

The layered structure G in the present invention is a term collectively referring to layers which work as a device and also to various layers to be added as needed, such as a nucleation layer and a stress control layer. In a HEMT structure shown in FIG. 3, the first layer 11 represents an electron transit layer, the second layer 12 represents an electron supply layer, the third layer 13 represents a diffusion suppression layer, and the fourth layer 13 represents a normally-off support layer.

While FIG. 3 shows an example including a HEMT, the nitride semiconductor substrate W is not limited thereto, but may have any structure in which the buffer layer B and the layered structure G are formed on the base substrate S, and accordingly the nitride semiconductor substrate W is preferably used also for other types of power devices capable of operating at higher frequency with higher breakdown voltage.

Known configurations (in terms of layer thickness and impurity concentration), are widely applicable to the first layer 11 and the second layer 12 having a wider band gap than the first layer 11, without any particular limitation. For example, the first layer 11 is made of GaN, AlGaN or the like, the second layer 12 is made of AlGaN, AlInGaN or the like. The thickness of the first layer 11 is approximately 300 to 3000 nm, and the thickness of the second layer 12 is approximately 10 to 100 nm.

A feature of the present invention lies in that the third layer 13, which has a thickness of 0.25 to 2 nm and has a wider band gap than the second layer 12, is provided as a diffusion suppression layer (hereinafter referred to as a “first diffusion suppression layer”). It should be noted that this diffusion suppression layer is extremely thin compared with a 25 nm-thick diffusion suppression layer used in the semiconductor device described in WO 2014/188715.

When a some sort of layer is interposed between any two layers and if these layers are different in lattice constant, thermal expansion coefficient and band gap energy, there occur stress generation, increase of dislocations and fluctuation in resistance or the like, at the interfaces. The third layer 13 provided as the diffusion suppression layer is desired to have only a function to prevent impurity diffusion from the fourth later 14, but is not desired to adversely affect the other layers.

A method for minimizing such adverse effects is that of setting the thickness of the layer to be as small as possible. For example, the 0.25 to 2 nm thickness described above corresponds to that composed of one to eight AlN molecules. The third layer 13 such as described above is normally made of AlN, AlGaN, AlInGa or the like, and is preferably made of AlN. AlN has a very high resistivity, and a diffusion suppression layer made of AlN effectively prevents the diffusion of Mg into the first layer and the second layer.

The fourth layer 14 (the normally-off support layer) containing 5E+18 atoms/cc or more of the P-type conductive impurity is formed on the third layer 13. In order to obtain normally-off operation, the fourth layer 14 needs to contain the P-type conductive impurity at a concentration of 5E+18 atoms/cc or more.

For the P-type conductive impurity, a wide variety of known materials whose doping in the nitride semiconductor induces P-type conductivity may be used. Examples of such a P-type conductive impurity are magnesium (Mg) and zinc (Zn). For example, the P-type conductive impurity is preferred to be Mg when the nitride semiconductor is GaN. For a method of the Mg doping, a wide variety of known technologies may be used.

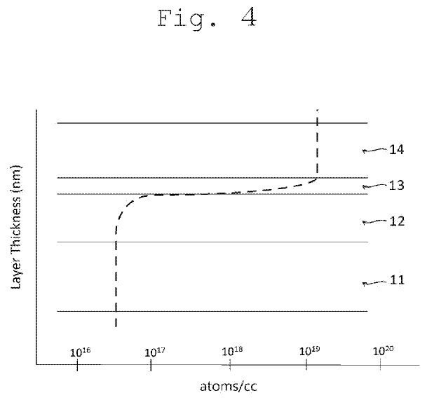

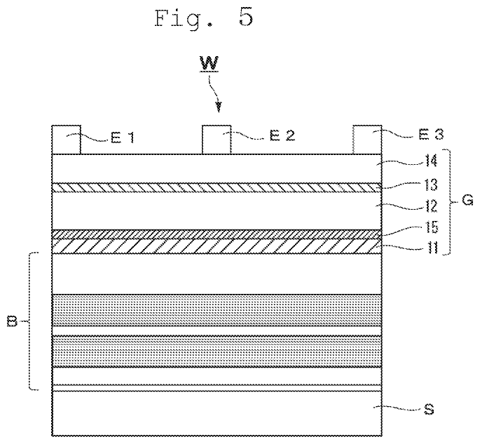

The concentration of P-type conductive impurity at an interface between the second layer 12 and the third layer 13 is one hundredth or less of that at an interface between the fourth layer 14 and the third layer 13. FIG. 4 is a schematic graph showing a concentration profile of the P-type conductive impurity.

The concentration of P-type conductive impurity at an interface between the second layer 12 and the third layer 13 is correlated with the concentration of P-type conductive impurity in the second layer 12. It can be said that when the former concentration is high, the latter is also high.

When the concentration of P-type conductive impurity at an interface between the second layer 12 and the third layer 13 is one hundredth or less of that at an interface between the fourth layer 14 and the third layer 13, characteristics of the second layer 12 working as an operation layer is not fatally impaired. While the ratio is desired to be as small as possible, there is a limit for lowering the ratio when MOCVD is used to build up the layers. One two-hundredth or less is more preferable within a practical range.

A more preferable embodiment of the present invention is the one provided with a fifth layer 15 (hereinafter referred to as a “second diffusion suppression layer”) which is made of a nitride semiconductor having a wider band gap than the second layer 12 and is 0.25 to 0.5 nm thick, between the first layer 11 and the second layer 12.

By thus providing the fifth layer 15, a configuration similar to that obtained by inserting so-called a spacer layer in a HEMT structure is obtained, and also a similar effect to that of the spacer layer is obtained. In the present invention, the fifth layer 15 reliably prevents diffusion of P-type conductive impurity slightly existing in the third layer 13 into the first layer 11, which makes it possible to keep the operation environment for a two dimensional electron gas (2DEG) in the first layer 11 in which a main current path of the HEMT is produced.

The thickness of the fifth layer 15 is set at 0.25 to 5 nm, similarly to that of the third layer 13, and it is preferably 1 to 3 nm. The thickness of the fifth layer 15 may be larger than that of the third layer 13 because the fifth layer 15 also works as a spacer layer. However, when the thickness exceeds 5 nm, stress at an interface may raise some problems.

The fifth layer 15 is made of a nitride semiconductor having a wider band gap than the second layer 12. It is in order to enable the fifth layer 15 to work as a spacer layer, as described above.

In a specific embodiment of the present invention, the first layer 11 is made of GaN, the second layer 12 is made of AlGaN, the third layer 13 and the fifth layer 15 are made of AlN, the fourth layer 14 is made of GaN, and the P-type conductive impurity is Mg. The AlGaN refers to AlₓGa₁₋ₓN (0<x<1).

Each of the layers constituting the nitride semiconductor substrate W of the present invention is usually deposited by epitaxial growth. The deposition is performed by common methods, such as CVD methods including MOCVD and plasma CVD (PECVD), a laser beam vapor deposition method, a sputtering method in atmosphere gases, a molecular beam epitaxy (MBE) method using a molecular beam under high vacuum, a metal-organic molecular beam epitaxy (MOMBE) method combining MOCVD with MBE. Source materials used for the epitaxial growth of the layers are not limited to those used in Examples, described later.

As has been described above, the nitride semiconductor substrate of the present invention can effectively prevent diffusion of P-type conductive impurity into the electron supply layer, while minimizing adverse effects of the inserted layer. A nitride semiconductor device prepared using the nitride semiconductor substrate according to the present invention can be utilized as a high performance semiconductor device.

### EXAMPLES

Hereinafter, the present invention will be described in detail with reference to examples, but the present invention is restricted to the examples.

### [Example 1]

A 6-inch P-type Si single crystal substrate of (111) plane orientation, used as the base substrate S, was cleaned up by a well-known substrate cleaning method, and was subsequently placed in an MOCVD apparatus. After substituting the inside of the apparatus with a carrier gas, the temperature was raised and the substrate was held at 950° C. in a 100% hydrogen atmosphere to remove a natural oxide film on the surface of the silicon single crystal.

Next, by vapor deposition using trimethylaluminum (TMAl), trimethylgallium (TMGa) and ammonia (NH₃) as source materials, an initial layer composed of a 100 nm-thick AlN layer and a 150 nm-thick Al_{0.28}Ga_{0.78}N thereon was grown and, on the initial layer, a repetition layer was grown by repeating alternate deposition of a 5 nm-thick AlN layer and a 30 nm-thick GaN layer eighty times. Thus formed structure including the initial layer and the repetition layer was used as the buffer layer B. In the deposition of the layers, the growth temperature and pressure were set at 1000° C. and 60 hPa, respectively, as approximate references, and were appropriately adjusted for each of the layers.

Then, a 100 nm-thick GaN layer as the first layer 1 and a 20 nm-thick Al_{0.22}Ga_{0.78}N layer as the second layer 2 were deposited in this order, to form the layered structure G (the operation layer). The layers were formed by setting the growth temperature and pressure at 1000° C. and 60 hPa, respectively, as approximate references, and appropriately adjusting them for each of the layers.

For the third layer 3, a 60 nm-thick GaN layer was used, Mg was used as the P-type conductive impurity therein, and biscyclopentadienylmagnesium (Cp₂Mg) was used as the Mg-containing source material. The growth temperature and pressure for the GaN layer formation were set at 950° C. and 200 hPa, respectively.

### [Comparative Example 1]

An evaluation sample for Comparative Example 1 was prepared in a manner similar to Example 1, except that, in the process of forming the third layer 3, instead of forming the GaN layer (but under the same formation conditions), only Cp₂Mg was initially supplied while NH₃ being supplied and, one minute later, TMGa was supplementarily supplied.

### [Comparative Example 2]

An evaluation sample for Comparative Example 2 was prepared in a manner similar to Comparative Example 1, except that the temperature was set at 1000° C. in the process of forming the third layer 3.

### [Comparative Example 3]

An evaluation sample for Comparative Example 3 was prepared in a manner similar to Comparative Example 1, except that the temperature was set at 900° C. in the process of forming the third layer 3.

### [Example 2]

An evaluation sample for Example 2 was prepared in a manner similar to Example 1, except that the concentration of the Mg source material was set at one third of that in Example 1.

### [Example 3]

An evaluation sample for Example 3 was prepared in a manner similar to Example 2, except that the thickness of the second layer was doubled, and that formation of the third layer was performed such that, similarly to Comparative Example 1, only Cp₂Mg was initially supplied while NH₃ being supplied and, one minute later, TMGa was supplied.

### [Evaluation 1: Mg Concentration]

Each of the evaluation samples was cleaved along the diametrical direction, and a fragment was sampled from around the center of the principal surface. By using SIMS, for each of the samples, a Mg concentration profile in the thickness direction from the surface of the third layer 3 to the first layer 1 was obtained. Values of the Mg concentration in the third layer 3 and that in the first layer 1, each defined in the previous descriptions, were read from the profiles.

### [Evaluation 2: Mobility]

Each of the evaluation samples was cut into a 7 mm square chip, four corners of the third layer 3 in each chip were etched to produce holes with a diameter of 0.25mm, and a Ti/Al electrode was formed at each of the holes by vacuum evaporation. After performing alloying heat treatment at 600° C. in a nitrogen atmosphere for 5 minutes, the chips were subjected to Hall effect measurement with HL5500PC produced by Nanometrics Japan. Levels of mobility were expressed in comparison with Comparative Example 1. Less than 1000 cm²/Vs was classified as “Not Good”, and 1000 cm²/Vs or more as “Good”, and samples with “Good” were determined to be passed.

Table 1 summarizes data and evaluation results for each sample.

TABLE 1

| | Mg concentration | Mg concentration | Mg | Decision |
|---|---|---|---|---|
| | \textcircled{3} in the | \textcircled{1} in the | Concentration | on Mobility |
| Evaluation | third layer 3 | first layer 1 | Ratio \textcircled{1}/\textcircled{3} | (“Good” or |
| Sample | (atoms/cm³) | (atoms/cm³) | (%) | “Not good”) |
| Example 1 | 2.0E+19 | 7.0E+17 | 3.5 | Good |
| Example 2 | 1.0E+19 | 7.0E+17 | 7.0 | Good |
| Example 3 | 1.0E+19 | 3.0E+17 | 3.0 | Good |
| Comparative | 4.0E+19 | 1.0E+19 | 25.0 | Not Good |
| Example 1 | | | | |
| Comparative | 4.0E+19 | 1.0E+19 | 25.0 | Not Good |
| Example 2 | | | | |
| Comparative | 4.0E+19 | 7.0E+18 | 17.5 | Not Good |
| Example 3 | | | | |

Table 1 clearly shows that the samples within the scope of the present invention each have a high mobility, while securing a Mg concentration of 5E+18 atoms/cm³ or more. The ratio of the Mg concentrations in the first layer 1 to that in the third layer 3 was 3.5% in Example 1 and 7% in Example 2, and the mobility in Example 1 was about 5% higher than that in Example 2. It accordingly can be said that a smaller Mg concentration ratio is desirable.

Formation of a GaN layer by an MOCVD method requires such a relatively high growth temperature as 1000° C., as exemplified in Examples of the present invention. This is because a low growth temperature causes deterioration of surface flatness of the GaN layer.

On the other hand, by lowering the growth temperature in forming the third layer 3, the Mg diffusion is relatively suppressed, which increases the effect of the present invention, that is to say, prevention of an adverse effect due to the Mg diffusion into the operation layer. Thus, it can be said that there is an optimum range of the growth temperature for achieving a balance between conflicting properties.

However, it has previously been impossible to simply determine such an optimum growth temperature range, because of limiting factors such as specifications and various characteristics required of a nitride semiconductor substrate as a whole, performance of a device to be used, growth conditions for the deposition, and various other conditions.

In the present invention, the surface flatness was focused on as a parameter in conflict with the prevention of Mg diffusion, and as a result, it has been found that a condition enabling formation of the layers at a relatively low temperature while maintaining the surface flatness can be determined by the size of pits appearing on the surface of the third layer 3.

Accordingly, in a more preferred embodiment of the present invention, the pits present on the surface of the third layer 3 are of a conical shape having an opening with an inner diameter of 10 nm or less at the surface, and the density of the pits is 1E+10/cm² or less.

The pits as in the present invention are shaped like so-called a mortar. The shape is a hole which has almost a circular opening at the surface of the third layer 3 and extends in a direction approximately perpendicular to the surface while reducing its diameter, and can also be said to be an inverse conical shape. It does not necessarily need to be of a precise conical shape, but may have some distortion and some flat portion at the bottom.

The openings of pits should not have an inner diameter of more than 10 nm, because such large pits themselves may deteriorate the overall flatness of the layer. As for the inner diameter, the smaller is the better, but it cannot be prevented from being equal to or larger than a certain degree of size, particularly when an MOCVD method is employed, and therefore the inner opening diameter of the pits according to the present invention is preferably 0.3 to 5 nm.

Pits having an inner diameter of 10 nm or less can better balance between the effect of the present invention and the surface flatness, as long as their density on the surface of the third layer 3 is 1E+10/cm² or less. As for the density, the lower is also the better, and practically 5E+8/cm² to 8E+9/cm² is preferable.

In the present invention, the pits have a depth of approximately 10 to 80 nm when generated to have an inner diameter of 10 nm or less, and this level is acceptable, while there is no restriction on the depth.

Such an inner diameter and density of pits can be attained by adjusting pressure and flow rates of the source gases or a carrier gas, as well as the growth temperature, in a timely manner.

The pits according to the present invention can be observed from the surface of the third layer 3 by using an atomic force microscope (AFM). However, other techniques, such as a method of cleaving the nitride semiconductor substrate and observing thus-obtained piece in the cross-sectional direction by a transmission electron microscope (TEM) or the like in order to determine the inner diameter of the pit's opening and to calculate the density from the number of pits per unit length, may be employed.

The above-described observation confirmed that in Example 1, no pits having an opening of a 10 nm or less inner diameter were detected in the surface of the third layer 3.

### [Comparative Example 4]

In order to make clear the effect of the present invention, an evaluation sample for Comparative Example 4 was prepared by changing the growth temperature for the third layer 3 in Example 1 to 800° C. The AFM observation confirmed that there existed pits having an opening with an inner diameter exceeding 10 nm at a density of 6E+9/cm².

According to cross-sectional observation using TEM that was also carried out, some dislocations in the third layer 3 were observed in Example 1, while Comparative Example 4 showed conical pits that gradually enlarged from the lower surface toward the upper surface in the third layer 3. Considering the pit density, it seems that the pit cross sections observed by TEM is that of pits with a larger opening diameter than 10 nm observed by AFM.

These results suggest that, in Comparative Example 4, sufficient thermal energy for epitaxial growth was not supplied because of the lower growth temperature compared with Example 1. Subsequently, electrodes were provided on the evaluation sample to produce a device for performance comparison. The result was such that large leak current was generated in the device of Comparative Example 4, indicating that the pits generated in the top layer of the sample exerted adverse effects.

### [Example 4]

A 6-inch P-type Si single crystal substrate of (111) plane orientation, used as the base substrate S, was cleaned up by a well-known substrate cleaning method, and was subsequently placed in an MOCVD apparatus. After substituting the inside of the apparatus with a carrier gas, the temperature was raised and the substrate was held at 1000° C. for 15 minutes in a 100% hydrogen atmosphere to remove a natural oxide film on the surface of the silicon single crystal.

Next, by vapor deposition using trimethylaluminum (TMAl), trimethylgallium (TMGa) and ammonia (NH₃) as source materials, an initial layer composed of a 100 nm-thick AlN layer and a 150 nm-thick Al_{0.2}Ga_{0.8}N layer thereon, a multilayer formed by alternately depositing a 5 nm-thick AlN layer and a 30 nm-thick Al_{0.2}Ga_{0.8}N layer eighty times, and a 1500 nm-thick GaN single layer were formed in this order. Thus formed layers were collectively used as the buffer layer B. In the deposition of the layers, the growth temperature and pressure were set at 1000° C. and 60 hPa, respectively, as approximate references, and were appropriately adjusted for each of the layers.

Then, to form the layered structure G (operation layer), a 100 nm-thick GaN layer as the first layer 11, a 20 nm-thick Al_{0.22}Ga_{0.78}N layer as the second layer 12, a 1 nm-thick AlN layer as the third layer 13, a 60 nm-thick GaN layer doped with a P-type conductive impurity, Mg, as the fourth layer 14 were stacked in this order. The growth temperature and pressure were set in conformity with the process of forming the buffer layer B, and biscyclopentadienylmagnesium (Cp₂Mg) was used as the Mg-containing source material. An evaluation sample for Example 4 was prepared by the above-described procedure.

### [Comparative Example 5]

An evaluation sample for Comparative Example 5 was prepared in a manner similar to Example 4 except that the fourth layer 14 was not deposited.

### [Evaluation 1: Layer Thickness and Mg Concentration]

As for layer thickness, each of the evaluation samples was cleaved along the diametrical direction and a fragment was sampled from around the center of the principal surface. The fragment was subjected to secondary ion mass spectrometry (SIMS) to obtain an Mg concentration profile in the thickness direction. From the profile, the ratio of the Mg concentration at an interface between the fourth layer 14 and the third layer 13 to that at an interface between the second layer 12 and the third layer 13 (hereinafter referred to as a “Mg ratio”) was calculated.

### [Evaluation 2: Mobility]

The evaluation samples, which were also used for STEM observation, were subjected to Hall effect measurement by the Van der Pauw method to evaluate the electron mobility. First, each of the evaluation samples was cut into a 7 mm square chip, and at four corners of the fourth layer 14 in each chip, a Ti/Al electrode with a diameter of 0.25 mm was formed by vacuum evaporation. After performing alloying heat treatment at 600° C. in a nitrogen atmosphere for 5 minutes, the chips were subjected to the Hall effect measurement with HL5500PC produced by Nanometrics Japan. Levels of the mobility were expressed in comparison with Comparative Example 5. 1 or less was classified as C, “Not Good”, 1.1 or less as B, “Good”, and 1.2 or more as A, “Excellent”. A and B were regarded as Examples.

### [Evaluation 3: Threshold Voltage]

The threshold voltage, which was used as an indicator of normally-off characteristics, was measured as follows: a recessed-gate Schottky electrode (Ni/Au) and source/drain Ohmic electrodes (Ti/Al) were formed on the fourth layer 14 of each of the prepared evaluation samples, on which device isolation was subsequently performed. After thus fabricating field effect transistor devices, their threshold voltages were obtained from I-V measurement using a curve tracer at room temperature. Each of the obtained threshold voltages was represented by its deviation from a reference value determined by regarding the threshold voltage for the sample of Comparative Example 5 as OV, the deviation being expressed in voltage.

As a result, in Example 4, the Mg ratio was 1/120, the mobility was A, and the threshold voltage was positive, while in Comparative Example 5 the mobility was C. Thus, the sample within the scope of the present invention exerted sufficient normally-off characteristics and high mobility.

The Mg concentration in the fourth layer 14 in Example 4 was 1E+19 atoms/cc.

### [Example 5]

An evaluation sample for Example 5 was prepared in a manner similar to Example 4 except that the growth temperature for the fourth layer 14 was set at 950° C.

As a result, the Mg ratio was 1/100, the mobility was A, and the threshold voltage was positive. The mobility was inferior to Example 4, which was caused by the larger Mg ratio, in other words, the smaller decreasing rate of Mg concentration compared with Example 4.

### [Example 6]

An evaluation sample for Example 6 was prepared in a manner similar to Example 4 except that the flow rate of Cp₂Mg was adjusted so that the Mg concentration in the fourth layer 14 be 5E+18 atoms/cc.

As a result, the Mg ratio was 1/105, the mobility was A, and the threshold voltage was positive. The threshold voltage was inferior to Example 4, which was caused by the smaller Mg concentration in the fourth layer 14 compared with Example 4.

### [Comparative Example 6]

An evaluation sample for Comparative Example 6 was prepared in a manner similar to Example 4 except that the growth temperature for the fourth layer 14 was set at 1030° C.

As a result, the Mg concentration in the fourth layer 14 was 1E+19 atoms/cc, the Mg ratio was 1/80, the mobility was C, and the threshold voltage was positive. The deterioration of mobility is caused by the decreasing rate of Mg concentration higher than 1/100.

### [Comparative Example 7]

An evaluation sample for Comparative Example 7 was prepared in a manner similar to Example 4 except that the flow rate of Cp₂Mg was adjusted so that the Mg concentration in the fourth layer 14 be 3E+18 atoms/cc.

As a result, the Mg ratio was 1/105, the mobility was A, and the threshold voltage was negative. The reason of the negative threshold voltage is that the Mg concentration in the fourth layer 14 is small.

Formation of a GaN layer by an MOCVD method requires such a relatively high growth temperature as 1000° C., as exemplified in Examples of the present invention. This is because a low growth temperature causes deterioration of surface flatness of the GaN layer.

On the other hand, by lowering the growth temperature in forming the fourth layer 14, the Mg diffusion is relatively prevented, which increases the effect of the present invention, that is to say, prevention of an adverse effect due to the Mg diffusion into the operation layer. Thus, it can be said that there is an optimum range of the growth temperature for achieving a balance between conflicting properties.

However, it has previously been impossible to simply determine such an optimum growth temperature range, because of limiting factors such as specifications and various characteristics required of the nitride semiconductor substrate as a whole, performance of a device to be used, growth conditions for the deposition, and various other conditions.

In the present invention, the surface flatness was focused on as a parameter in conflict with the prevention of Mg diffusion, and as a result, it has been found that a condition enabling formation of the layers at a relatively low temperature while maintaining the surface flatness can be determined by the size of pits appearing on the surface of the fourth layer 14.

Accordingly, in a more preferred embodiment of the present invention, pits existing on the surface of the fourth layer 14 are of a conical shape having an opening with an inner diameter of 10 nm or less at the surface, and the density of the pits is 1E+10/cm² or less.

The pits as in the present invention are shaped like so-called a mortar. The shape is a hole which has almost a circular opening at the surface of the fourth layer 14 and extends in a direction approximately perpendicular to the surface while reducing its diameter, and can also be said to be an inverse conical shape. It does not necessarily need to be of a precise conical shape, but may have some distortion and some flat portion at the bottom.

The openings of pits should not have an inner diameter of more than 10 nm, because such large pits themselves may deteriorate the overall flatness of the layer. The inner diameter is desired to be as small as possible, but it cannot be prevented from being equal to or larger than a certain degree of size, particularly when an MOCVD method is employed, and therefore the inner opening diameter of pits according to the present invention is preferably 0.3 to 5 nm.

Pits having an inner opening diameter of 10 nm or less can better balance between the effect of the present invention and the surface flatness, as long as their density is 1E+10/cm² or less on the surface of the fourth layer 14. As for the density, the lower is the better, and practically 5E+8/cm² to 8E+9/cm² is preferable.

In the present invention, the pits have a depth of approximately 10 to 80 nm, when generated to have an inner diameter of 10 nm or less, and this level is acceptable, while there is no restriction on the depth.

Such an inner diameter and density of pits are attained by adjusting pressure and flow rates of the source gases or a carrier gas, as well as the growth temperature, in a timely manner.

The pits according to the present invention can be observed from the surface of the fourth layer 14 by using an atomic force microscope (AFM). However, other techniques, such as a method of cleaving the nitride semiconductor substrate and observing thus-obtained piece in the cross-sectional direction by a transmission electron microscope (TEM) or the like, in order to determine the inner diameter of the pit's opening and to calculate the density from the number of pits per unit length, may also be employed.

According to the above-described observation performed on the Example 4, there were no pits having an opening of a 10 nm or less inner diameter on the surface of the fourth layer 14 in Example 4.

### [Comparative Example 8]

In order to make clear the effect of the present invention, an evaluation sample for Comparative Example 8 was prepared by changing the growth temperature for the fourth layer 14 in Example 4 to 800° C. The AFM observation confirmed that there existed pits having an opening with an inner diameter exceeding 10 nm at a density of 6E+9/cm².

According to cross-sectional observation using TEM that was also carried out, some dislocations in the third layer 13 were observed in Example 4, while Comparative Example 8 showed conical pits that gradually enlarged from the lower surface toward the upper surface in the third layer 13. Considering the pit density, it seems that the pit cross sections observed by TEM is that of pits with a larger opening diameter than 10 nm observed by AFM.

These results suggest that, in Comparative Example 8, sufficient thermal energy for epitaxial growth was not supplied because of the lower growth temperature compared with Example 4. Subsequently, electrodes were provided on the evaluation sample to produce a device for performance comparison. The result was such that large leak current was generated in the device of Comparative Example 8, indicating that the pits generated in the top layer of the sample exerted adverse effects.

What is claimed is:

1. A nitride semiconductor substrate comprising at least a layered structure made of group 13 nitride semiconductors, wherein
a first layer, a second layer having a wider band gap than the first layer, and a third layer containing a P-type conductive impurity at a concentration of 5E+18 atoms/cm³ or more are stacked in this order in the layered structure, and
a maximum concentration of P-type conductive impurity in the first layer is 10% or less of a concentration of P-type conductive impurity in the third layer.

2. The nitride semiconductor substrate according to claim 1, wherein the first layer is made of GaN, the second layer is made of AlGaN, the third layer is made of GaN, and the P-type conductive impurity is Mg.

3. The nitride semiconductor substrate according to claim 1, wherein the layered structure is formed on a base substrate with a buffer layer made of nitride semiconductors interposed therebetween.

4. The nitride semiconductor substrate according to claim 2, wherein the layered structure is formed on a base substrate with a buffer layer made of nitride semiconductors interposed therebetween.

5. The nitride semiconductor substrate according to claim 1, wherein the third layer has pits on the surface, the pits are of a conical shape having an opening of a 10 nm or less inner diameter at the surface, and a density of the pits is 1E+10/cm² or less.

6. The nitride semiconductor substrate according to claim 2, wherein the third layer has pits on the surface, the pits are of a conical shape having an opening of a 10 nm or less inner diameter at the surface, and a density of the pits is 1E+10/cm² or less.

7. The nitride semiconductor substrate according to claim 3, wherein the third layer has pits on the surface, the pits are of a conical shape having an opening of a 10 nm or less inner diameter at the surface, and a density of the pits is 1E+10/cm² or less.

8. The nitride semiconductor substrate according to claim 4, wherein the third layer has pits on the surface, the pits are of a conical shape having an opening of a 10 nm or less inner diameter at the surface, and a density of the pits is 1E+10/cm² or less.

9. A nitride semiconductor substrate comprising at least a layered structure made of group 13 nitride semiconductors, wherein
a first layer, a second layer having a wider band gap than the first layer, a third layer having a thickness of 0.25 to 2 nm and a wider band gap than the second layer, and a fourth layer containing a P-type conductive impurity at a concentration of 5E+18 atoms/cc or more are stacked in this order in the layered structure, and
a concentration of the P-type conductive impurity at an interface between the second layer and the third layer is one hundredth or less of a concentration of the P-type conductive impurity at an interface between the fourth layer and the third layer.

10. The nitride semiconductor substrate according to claim 9, wherein a fifth layer made of a nitride semiconductor is further provided between the first layer and the second layer, the fifth layer having a thickness of 0.25 to 5 nm and having a wider band gap than the second layer.

11. The nitride semiconductor substrate according to claim 9, wherein the first layer is made of GaN, the second layer is made of AlGaN, the third layer and the fifth layer are made of AlN, the fourth layer is made of GaN, and the P-type conductive impurity is Mg.

12. The nitride semiconductor substrate according to claim 10, wherein the first layer is made of GaN, the second layer is made of AlGaN, the third layer and the fifth layer are made of AlN, the fourth layer is made of GaN, and the P-type conductive impurity is Mg.

13. The nitride semiconductor substrate according to claim 9, wherein the layered structure is formed on a base substrate with a buffer layer made of nitride semiconductors interposed therebetween.

14. The nitride semiconductor substrate according to claim 10, wherein the layered structure is formed on abase substrate with a buffer layer made of nitride semiconductors interposed therebetween.

15. The nitride semiconductor substrate according to claim 11, wherein the layered structure is formed on abase substrate with a buffer layer made of nitride semiconductors interposed therebetween.

16. A nitride semiconductor device prepared using the nitride semiconductor substrate according to claim 1.

17. A nitride semiconductor device prepared using the nitride semiconductor substrate according to claim 9.
